(19) United States
(12) Patent Application Publication
(10) Pub. No.: US 2026/0215121 A1
(43) Pub. Date: Jul. 23, 2026

(54) DISPLAY PANEL AND DISPLAY DEVICE

(71) Applicant: Wuhan Tianma MicroElectronics Co., Ltd. Shanghai Branch., Shanghai (CN)

(72) Inventors: Huiping CHAI, Shanghai (CN); Bing HAN, Shanghai (CN); Tingting LIU, Shanghai (CN); Lin ZHANG, Shanghai (CN); Xiaowen WANG, Shanghai (CN)

(21) Appl. No.: 19/268,504

(22) Filed: Jul. 14, 2025

(30) Foreign Application Priority Data
Jan. 22, 2025 (CN) 202510104614.2

(51) Int. Cl. H10K 59/35; H10K 59/122

(52) U.S. Cl. CPC H10K 59/353; H10K 59/122; H10K 59/352

(57) ABSTRACT

A display panel includes a pixel definition layer including pixel openings. First column of pixel openings and second column of pixel openings are arranged along a first direction. The first column of pixel openings includes a first pixel opening and a second pixel opening periodically arranged along a second direction. In the second direction and in the second column of pixel openings, a spacing between an i-th third pixel opening and an (i+1)-th third pixel opening is d1, a spacing between the (i+1)-th third pixel opening and an (i+2)-th third pixel opening is d2, d1≠d2, i is a positive integer not greater than N-2, and N is an integer greater than 4. In the second direction, a spacing between adjacent first and second pixel openings is d3. The first, second, and third pixel openings are provided with first, second, and third light-emitting functional layers, respectively, d1≥d3, and d2≥d3.

### CROSS-REFERENCE TO RELATED APPLICATION

This application claims the priority of Chinese Patent Application No. CN 2025101046142, filed on Jan. 22, 2025, the entire content of which is incorporated herein by reference.

### FIELD OF THE DISCLOSURE

The present disclosure generally relates to the field of display technology, and more particularly to a display panel and a display device thereof.

### BACKGROUND

Organic light-emitting diode (OLED) display panel is a display screen made of organic light-emitting diodes, which has the characteristics of self-luminescence, high contrast, wide viewing angle, fast response, and low power consumption. The OLED display panel does not require a backlight source, and each pixel emits light independently, which can provide more realistic black and richer colors. As a result, applications of OLED display panels have become more and more extensive for various display devices. Therefore, how to provide a display quality of OLED display panels has become a research hotspot for those skilled in the art.

### SUMMARY OF THE DISCLOSURE

One embodiment of the present disclosure provides a display panel. The display panel includes an array substrate; a pixel definition layer located on a side of the array substrate, the pixel definition layer including a plurality of pixel openings; and a light-emitting functional layer located within a pixel opening of the plurality of pixel openings. The plurality of pixel openings includes a first column of pixel openings and a second column of pixel openings arranged along a first direction, the first column of pixel openings including a first pixel opening and a second pixel opening periodically arranged along a second direction, the second column of pixel openings including an i-th third pixel opening, an (i+1)-th third pixel opening and an (i+2)-th third pixel opening arranged along the second direction, i being an integer not less than 1. In the second direction, a spacing is between the i-th third pixel opening and the (i+1)-th third pixel opening is d1, a spacing is between the (i+1)-th third pixel opening and the (i+2)-th third pixel opening is d2, d1≠d2, i is a positive integer not greater than N-2, and N is an integer greater than 4. In the second direction, a spacing is between adjacent first and second pixel openings is d3. The first pixel opening is provided with a first light-emitting functional layer, the second pixel opening is provided with a second light-emitting functional layer, and the third pixel opening is provided with a third light-emitting functional layer; d1≥d3, and d2≥d3.

Another embodiment of the present disclosure provides a display device. The display device includes a display panel. The display panel includes an array substrate; a pixel definition layer located on a side of the array substrate, the pixel definition layer including a plurality of pixel openings; and a light-emitting functional layer located within a pixel opening of the plurality of pixel openings. The plurality of pixel openings includes a first column of pixel openings and a second column of pixel openings arranged along a first direction, the first column of pixel openings including a first pixel opening and a second pixel opening periodically arranged along a second direction, the second column of pixel openings including an i-th third pixel opening, an (i+1)-th third pixel opening and an (i+2)-th third pixel opening arranged along the second direction, i being an integer not less than 1. In the second direction, a spacing is between the i-th third pixel opening and the (i+1)-th third pixel opening is d1, a spacing is between the (i+1)-th third pixel opening and the (i+2)-th third pixel opening is d2, d1≠d2, i is a positive integer not greater than N-2, and N is an integer greater than 4. In the second direction, a spacing is between adjacent first and second pixel openings is d3. The first pixel opening is provided with a first light-emitting functional layer, the second pixel opening is provided with a second light-emitting functional layer, and the third pixel opening is provided with a third light-emitting functional layer; d1≥d3, and d2≥d3.

### BRIEF DESCRIPTION OF THE DRAWINGS

The following drawings are merely examples for illustrative purposes according to various disclosed embodiments and are not intended to limit the scope of the present disclosure.

FIG. 1 is a cross-sectional view of a display panel according to an embodiment of the present disclosure.

FIG. 2 is a partial schematic diagram of an arrangement of pixel openings in the display panel according to an embodiment of the present disclosure.

FIG. 3 is a partial schematic diagram of the arrangement of pixel openings in another display panel according to an embodiment of the present disclosure.

FIG. 4 is a partial schematic diagram of the arrangement of pixel openings in another display panel according to an embodiment of the present disclosure.

FIG. 5 is a partial schematic diagram of the arrangement of pixel openings in another display panel according to an embodiment of the present disclosure.

FIG. 6 is a partial schematic diagram of the arrangement of pixel openings in another display panel according to an embodiment of the present disclosure.

FIG. 7 is a partial schematic diagram of the arrangement of pixel openings in another display panel according to an embodiment of the present disclosure.

FIG. 8 is a partial schematic diagram of the arrangement of pixel openings in another display panel according to an embodiment of the present disclosure.

FIG. 9 is a partial schematic diagram of the arrangement of pixel openings in another display panel according to an embodiment of the present disclosure.

FIG. 10 is a partial schematic diagram of the arrangement of pixel openings in another display panel according to an embodiment of the present disclosure.

FIG. 11 is a partial schematic diagram of the arrangement of pixel openings in another display panel according to an embodiment of the present disclosure.

FIG. 12 is a partial schematic diagram of the arrangement of pixel openings in another display panel according to an embodiment of the present disclosure.

FIG. 13 is a partial schematic diagram of the arrangement of pixel openings in another display panel according to an embodiment of the present disclosure.

FIG. 14 is a partial schematic diagram of the arrangement of pixel openings in another display panel according to an embodiment of the present disclosure.

FIG. 15 is a partial schematic diagram of the arrangement of pixel openings in another display panel according to an embodiment of the present disclosure.

FIG. 16 is a partial schematic diagram of the arrangement of pixel openings in another display panel according to an embodiment of the present disclosure.

FIG. 17 is a partial schematic diagram of the arrangement of pixel openings in another display panel according to an embodiment of the present disclosure.

FIG. 18 is a cross-sectional view of the display panel shown in FIG. 17 along FF′.

FIG. 19 is the cross-sectional view of the display panel shown in FIG. 17 along MM′.

FIG. 20 is the cross-sectional view of the display panel shown in FIG. 17 along NN′.

FIG. 21 is another cross-sectional view of the display panel shown in FIG. 17 along NN′.

FIG. 22 is another cross-sectional view of the display panel shown in FIG. 17 along NN′.

FIG. 23 is a schematic diagram of a display device according to an embodiment of the present disclosure.

### DETAILED DESCRIPTION

Reference will now be made in detail to exemplary embodiments of the disclosure, which are illustrated in accompanying drawings. Wherever possible, same reference numbers will be used throughout drawings to refer to same or like parts.

A following will be combined with drawings in embodiments of the present disclosure to clearly and completely describe embodiments in the present disclosure. Obviously, described embodiments are only part of embodiments of the present disclosure, not all of embodiments. Based on embodiments in the present disclosure, all other embodiments obtained by ordinary technicians in a field without creative work are within a scope of protection of the present disclosure.

It is obvious to those skilled in the art that various modifications and changes can be made in the present disclosure without departing from a spirit or scope of the present disclosure. Therefore, the present disclosure is intended to cover modifications and changes of the present disclosure that fall within the scope of corresponding claims (technical solutions claimed for protection) and their equivalents. It should be noted that implementation methods provided in embodiments of the present disclosure can be combined with each other without contradiction.

In order to make above-mentioned purposes, features, and advantages of the present disclosure more obvious and easier to understand, the present disclosure is further described in detail in combination with drawings and specific implementation methods.

As shown in the background technology section, how to optimize a display quality of OLED display panels has become a research hotspot for those skilled in the art.

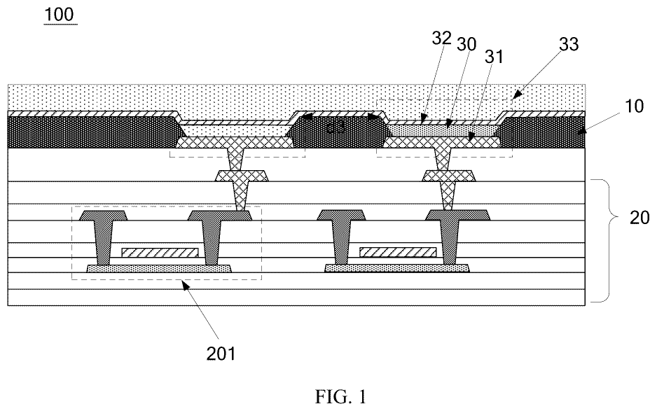

In view of this, an embodiment of the present disclosure provides a display panel, as shown in FIG. 1, an exemplary display panel 100 includes: an array substrate 20; a pixel definition layer 10 located on one side of the array substrate 20, the pixel definition layer 10 including a plurality of pixel openings; a light-emitting functional layer 30 located in the pixel opening, the light-emitting functional layer being an OLED.

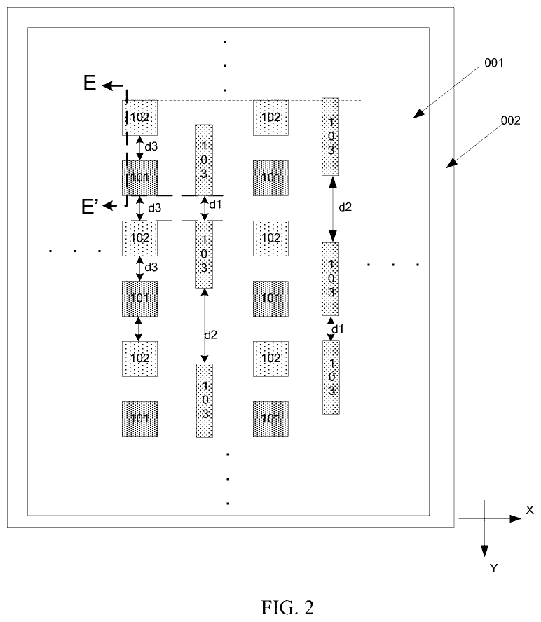

Referring to FIG. 2, FIG. 1 is a cross-sectional view of FIG. 2 along the EE′ direction, the display panel includes a display area 001 and a frame area 002 surrounding the display area 001, a plurality of pixel openings is located in the display area 001, the plurality of pixel openings includes: the first column of pixel openings and the second column of pixel openings are arranged along the first direction X, the first column of pixel openings includes the first pixel openings 101 and the second pixel openings 102 periodically arranged along the second direction Y, and the second column of pixel openings includes an i-th third pixel opening 103, an (i+1)-th third pixel opening 103 and an (i+2)-th third pixel opening 103 arranged along the second direction Y, i is an integer not less than 1. Among them, the first pixel opening 101 is provided with a first light-emitting functional layer, a second pixel opening 102 is provided with a second light-emitting functional layer, and the third pixel opening 103 is provided with a third light-emitting functional layer; in order to facilitate the illustration that different pixel openings correspond to different light-emitting functional layers, different colors are used in FIG. 2 to illustrate the first pixel opening 101, the second pixel opening 102 and the third pixel opening 103, but in actual production, multiple pixel openings can be formed at the same time.

Optionally, in one embodiment of the present disclosure, as shown in FIG. 1, the display panel 100 further includes: an anode layer 31 located on a side of the light-emitting functional layer 30 facing the array substrate 20 and a cathode layer 32 located on the side of the light-emitting functional layer 30 away from the array substrate 20; a pixel circuit 201 is provided in the array substrate 20, and one pixel circuit 201 corresponds to one light-emitting functional layer 30, which is used to control a voltage on the anode layer 31 corresponding to the light-emitting functional layer 30, thereby controlling the light-emitting state of the light-emitting functional layer 30 by controlling a voltage difference between the anode layer 31 and the cathode layer 32 corresponding to the light-emitting functional layer 30, so as to control the display of the display panel. Among them, one light-emitting functional layer 30 and its corresponding pixel circuit 201, anode layer 31, and cathode layer 32 constitute one pixel 33, and one pixel 33 corresponds to one pixel opening.

Optionally, different light-emitting functional layers in the display panel can share the same cathode layer to simplify the manufacturing process of the cathode layer, but the present disclosure does not limit this, and the sharing of the same cathode depends on a specific situation.

It should be noted that, in the present embodiment, as shown in FIG. 2, in the second direction Y, a spacing between the i-th third pixel opening 103 and the (i+1)-th third pixel opening 103 is d1, and a spacing between the (i+1)-th third pixel opening 103 and the (i+2)-th third pixel opening 103 is d2, d1≠d2, i is any positive integer not greater than N-2, and N is an integer greater than 4, so that during a formation of the third light-emitting functional layer, the i-th third light-emitting functional layer and the (i+1)-th third light-emitting functional layer can share an opening of a mask, thereby improving the i-th third light-emitting functional layer and the (i+1)-th third light-emitting functional layer. An aperture ratio of the third light-emitting functional layer of the display panel is improved, or the (i+1)-th third light-emitting functional layer and the (i+2)-th third light-emitting functional layer can share the opening of the mask plate, thereby improving the aperture ratio of the third light-emitting functional layer of the display panel and the display quality of the display panel, that is, using two third light-emitting functional layers adjacent to each other in the second direction Y and with a small interval to share the opening of the mask plate to improve the aperture ratio of the third light-emitting functional layer of the display panel, and then under the same driving signal, improve the display brightness of the third light-emitting functional layer of the display panel, and finally improve the display quality of the display panel.

It should be noted that if a distance between two adjacent third pixel openings 103 in the second direction Y is too small, when a light modulation layer is added to the side of the pixel definition layer 10 away from the array substrate 20 in the display panel, the light modulation layer can only be set above a gap between other adjacent pixel openings, but cannot be set above a gap between the two adjacent third pixel openings 103 with a smaller distance, such as color deviation or dispersion, which may cause poor display phenomena and affect the display quality.

In the present embodiment, in the second direction Y, the spacing between an adjacent first pixel opening 101 and the second pixel opening 102 is d3, d1≥d3, and d2≥d3, so that the light modulation layer can be set above the gap between any two adjacent third pixel openings 103 in the second direction Y by increasing the distance between the two adjacent third pixel openings 103 with a smaller distance, thereby alleviating a phenomenon of poor display quality caused by the small size of the gap between some adjacent third pixel openings 103 and an inability to set the light modulation layer, thereby improving the display quality of the display panel.

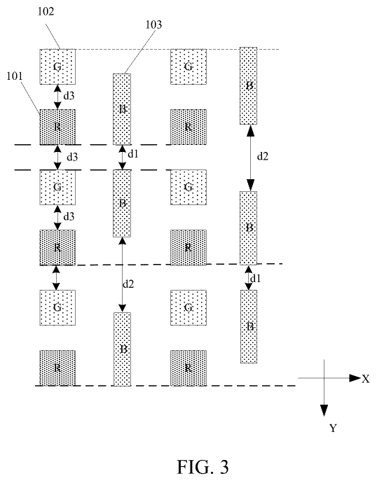

Since the luminous efficiency of a blue pixel is lower than that of the red pixel and the green pixel, in an optional embodiment of the present disclosure, as shown in FIG. 3, a red luminous function layer R is provided in the first pixel opening 101, a green luminous function layer G is provided in the second pixel opening 102, and a blue luminous function layer B is provided in the third pixel opening 103, so as to balance the luminous brightness of the red luminous function layer R, the green luminous function layer G and the blue luminous function layer B under the same driving signal, but the present disclosure does not limit this, and luminous functions depend on a specific situation.

The following describes the display panel provided in the embodiment of the present disclosure by taking the red luminous function layer R provided in the first pixel opening 101, the green luminous function layer G provided in the second pixel opening 102, and the blue luminous function layer B provided in the third pixel opening 103 as an example.

It should be noted that in the present embodiment, d1 can be less than d2 or greater than d2, and the present disclosure does not limit this, and d1 depends on a specific situation. For the convenience of description, the display panel provided in the embodiment of the present disclosure is described below by taking d1<d2 as an example.

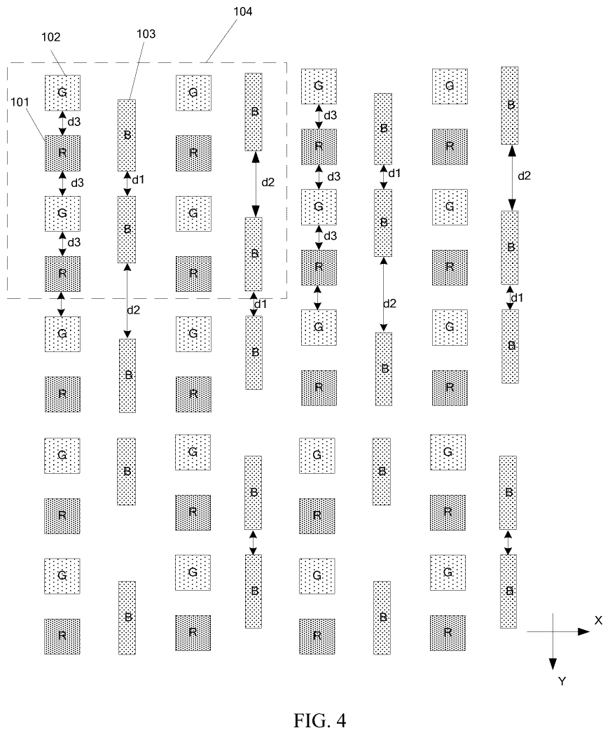

As shown in FIG. 4, in the present embodiment, in the second direction Y, the spacing between the (2k+1) third pixel opening 103 and the (2k+2) third pixel opening 103 is d1, and k is any integer not less than 0; in the second direction Y, the spacing between the (2j+2) third pixel opening 103 and the (2j+3) third pixel opening 103 is d2, and j is any integer not less than 0, so that an arrangement of third pixel openings 103 provided in the embodiment of the present disclosure is extended to the entire display area of the display panel, thereby further improving the display quality of the display panel.

In other embodiments of the present disclosure, as shown in FIG. 5, the spacing between the (2k+1) third pixel opening 103 and the (2k+2) third pixel opening 103 in the second direction Y is d2, and k is any integer not less than 0; in the second direction Y, the spacing between the (2j+2) third pixel opening 103 and the (2j+3) third pixel opening 103 is d1, and j is any integer not less than 0, so that the arrangement of third pixel openings 103 provided in the embodiment of the present disclosure is extended to the entire display area of the display panel, thereby further improving the display quality of the display panel. In various embodiments, the spacing depends on a specific situation.

In the embodiment of the present disclosure, the display panel includes a plurality of repeating units arranged in a display, and a repeating unit 104 involves four columns of pixel openings in the first direction X, specifically two columns of first column pixel openings and two columns of second column pixel openings, and involves four adjacent rows of pixel openings in the second direction Y. As shown in FIG. 4, the repeating unit 104 includes four first pixel openings 101, four second pixel openings 102, and four third pixel openings 103, wherein two first pixel openings 101 and two second pixel openings 102 are located in the first column and arranged crosswise in the second direction Y, and another two first pixel openings 101 and two second pixel openings 102 are located in the third column and arranged crosswise in the second direction Y, and two third pixel openings 103 are located in the second column, and the distance between the two third pixel openings 103 is d1, and another two third pixel openings 103 are located in the fourth column, and the distance between the two third pixel openings 103 is d2.

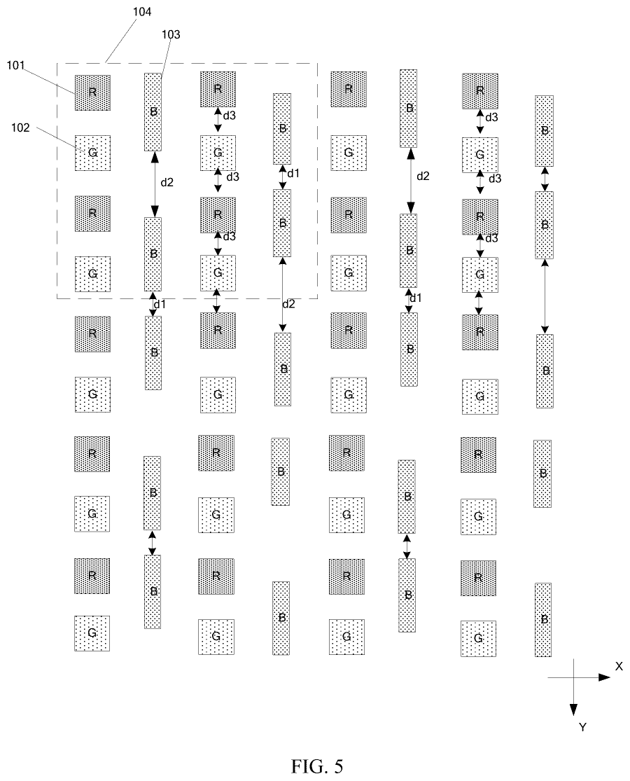

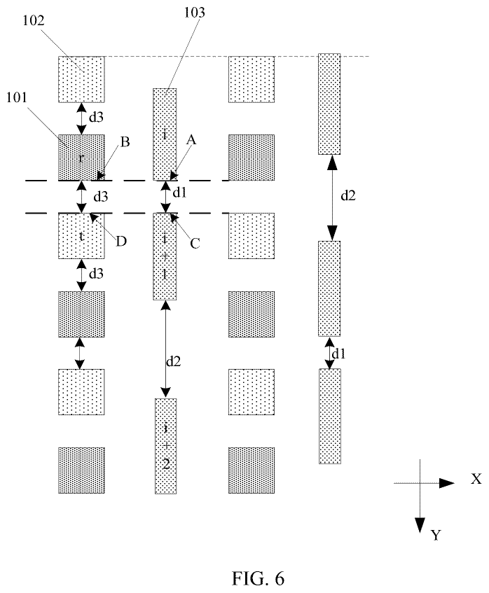

Optionally, in one embodiment of the present disclosure, as shown in FIG. 6, the i-th third pixel opening 103 and a r-th first pixel opening 101 are located in the same row, the (i+1)-th third pixel opening 103 and the t-th second pixel opening 102 are located in the same row, and the r-th first pixel opening 101 and the t-th second pixel opening 102 are located in adjacent rows, wherein r is an integer not less than 1, and t is an integer not less than 1.

Based on above embodiments, in one embodiment of the present disclosure, as shown in FIG. 6, d1=d3, that is, the spacing between the i-th third pixel opening 103 and the (i+1)-th third pixel opening 103 is the same as the spacing between the r-th first pixel opening 101 and the t-th second pixel opening 102, so that the distance between two adjacent third pixel openings 103 with a smaller distance is increased to the same as the distance between the first pixel opening 101 and the second pixel opening 102 adjacent in the second direction Y, so that the light modulation layer can be set above the gap between any two adjacent third pixel openings 103 in the second direction Y, thereby alleviating the phenomenon of poor display quality caused by the small size of the gap above some adjacent third pixel openings 103 and the inability to set the light modulation layer, thereby improving the display quality of the display panel.

It should be noted that, in an above embodiment, as shown in FIG. 6, in the second direction Y, the i-th third pixel opening 103 has a first position A toward a boundary of the (i+1)-th third pixel opening 103, and the r-th first pixel opening 101 has a second position B toward a boundary of the t-th second pixel opening 102; in the second direction Y, the (i+1)-th third pixel opening 103 has a third position C toward a boundary of the i-th third pixel opening 103, and the t-th second pixel opening 102 has a fourth position D toward a boundary of the r-th first pixel opening 101.

Optionally, in one embodiment of the present disclosure, in the second direction Y, the first position A and the second position B are the same, and the third position C and the fourth position D are the same, so that the boundary of the i-th third pixel opening 103 toward the (i+1)-th third pixel opening 103 is flush with the boundary of the r-th first pixel opening 101 toward the t-th second pixel opening 102 in the second direction Y, and the boundary of the (i+1)-th third pixel opening 103 toward the i-th third pixel opening 103 and the boundary of the t-th second pixel opening 102 toward the r-th first pixel opening 101 are flush in the second direction Y, that is, the lower edge of the i-th third pixel opening 103 is flush with the lower edge of the r-th first pixel opening 101, and the upper edge of the (i+1)-th third pixel opening 103 is flush with the upper edge of the t-th second pixel opening 102.

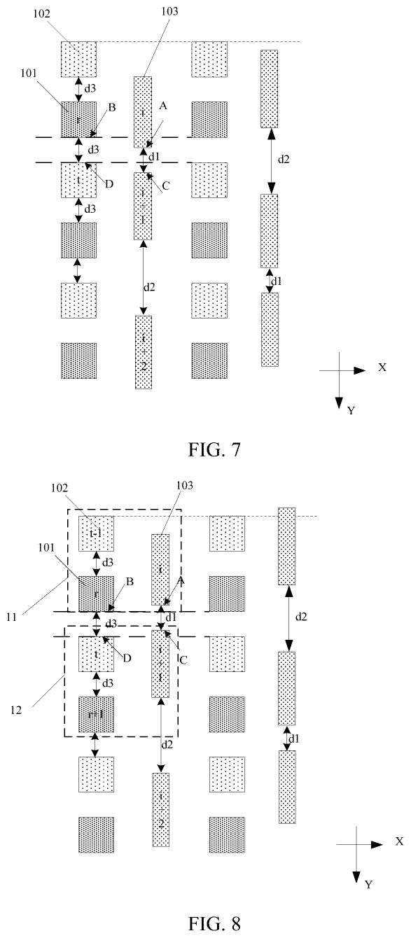

In another embodiment of the present disclosure, as shown in FIG. 7 and FIG. 8, in the second direction Y, the first position A and the second position B are different, and the third position C and the fourth position D are different, so that the boundary of the i-th third pixel opening 103 toward the (i+1)-th third pixel opening 103 and the boundary of the r-th first pixel opening 101 toward the t-th second pixel opening 102 are not flush in the second direction Y, and the boundary of the (i+1)-th third pixel opening 103 toward the i-th third pixel opening 103 and the boundary of the t-th second pixel opening 102 toward the r-th first pixel opening 101 are not flush in the second direction Y, that is, the lower edge of the i-th third pixel opening 103 is not flush with the lower edge of the r-th first pixel opening 101, and the upper edge of the (i+1)-th third pixel opening 103 is not flush with the upper edge of the t-th second pixel opening 102.

Optionally, based on above embodiments, in one embodiment of the present disclosure, as shown in FIG. 7, in the second direction Y, the first position A is located on the side of the second position B toward the fourth position D, and the third position C is located on the side of the fourth position D away from the second position B; in another embodiment of the present disclosure, as shown in FIG. 8, in the second direction Y, the first position A is located on the side of the second position B away from the fourth position D, and the third position C is located on the side of the fourth position D toward the second position B.

Continuing as shown in FIG. 8, in an embodiment of the present disclosure, the display panel includes a plurality of pixel unit areas, one pixel unit area includes a first pixel opening 101, the second pixel opening 102 and a third pixel opening 103, and optionally, in one embodiment of the present disclosure, the t-1th second pixel opening 102, the r-th first pixel opening 101 and the i-th third pixel opening 103 constitute a first pixel unit area 11, and the t-th second pixel opening 102, the (r+1)-th first pixel opening 101 and the (i+1)-th third pixel opening 103 constitute the second pixel unit area 12. It should be noted that, in this embodiment, the first position A is located on the side of the fourth position D toward the second position B, that is, in the second direction Y, the lower edge of the i-th third pixel opening 103 will not exceed the upper edge of the t-th second pixel opening 102, and the third position C is located on the side of the second position B toward the fourth position D, that is, in the second direction Y, the upper edge of the (i+1)-th third pixel opening 103 will not exceed the lower edge of the r-th first pixel opening 101, so that the display effects of the display areas corresponding to the first pixel unit area 11 and the second pixel unit area 12 can be independent of each other, reducing the mutual influence between the display contents corresponding to the first pixel unit area 11 and the second pixel unit area 12.

It should be noted that, under a premise of d1=d3, compared with the first position A and the second position B being different, and the third position C and the fourth position D being different in the second direction Y, the first position A and the second position B are the same, and the third position C and the fourth position D are the same in the second direction Y, which has a better effect on improving the display quality of the display panel. That is, compared with the arrangement of pixels in the display panel in FIG. 7 and FIG. 8, the arrangement of the display panel in FIG. 6 is more effective in improving the display quality of the display panel.

In another embodiment of the present disclosure, d1>d3, that is, the spacing between the i-th third pixel opening 103 and the (i+1)-th third pixel opening 103 is greater than the spacing between the r-th first pixel opening 101 and the t-th second pixel opening 102, so that the distance between two adjacent third pixel openings 103 with a smaller distance is increased to be greater than the distance between the adjacent first pixel opening 101 and the second pixel opening 102 in the second direction Y, so that the light modulation layer can be set above the gap between any two adjacent third pixel openings 103 in the second direction Y, thereby alleviating the phenomenon that the display quality deteriorates due to the small size above the gap between some adjacent third pixel openings 103 and the inability to set the light modulation layer, thereby improving the display quality of the display panel.

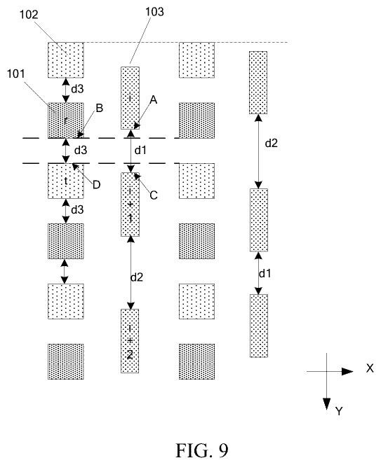

In addition, d1>d3, that is, the spacing between the i-th third pixel opening 103 and the (i+1)-th third pixel opening 103 is greater than the spacing between the r-th first pixel opening 101 and the t-th second pixel opening 102. Under the premise that a size of an evaporation opening of the mask for making the third pixel opening 103 remains unchanged, an aspect ratio of the third pixel opening 103 can be reduced, that is, the aspect ratio of the third pixel opening 103 shown in FIG. 9 is smaller than the aspect ratio of the third pixel opening 103 in FIG. 6-FIG. 8, thereby alleviating a color deviation or dispersion caused by the different length and width of the third light-emitting functional layer. Display quality of the display panel is improved.

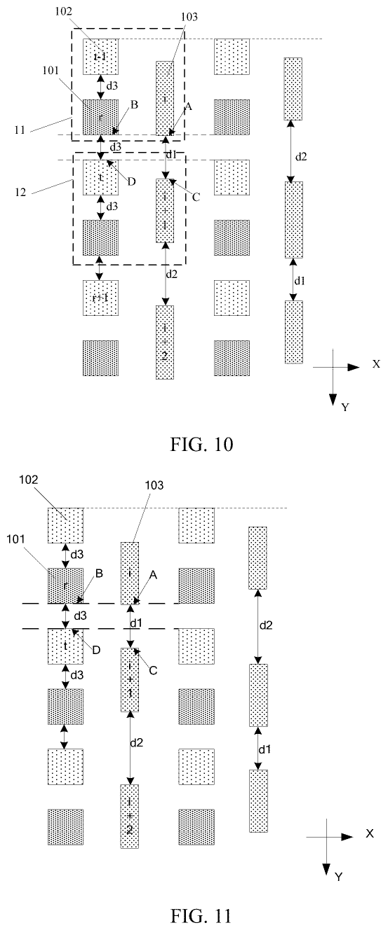

Optionally, in the above embodiment, as shown in FIGS. 10-12, in the second direction Y, the first position A is located on the side of the fourth position D toward the second position B, and the third position C is located on the side of the second position B toward the fourth position D, so that the display effects of the display areas corresponding to the first pixel unit area 11 and the second pixel unit area 12 can be independent of each other, reducing the mutual influence between the display contents corresponding to the first pixel unit area 11 and the second pixel unit area 12. However, this application does not limit this, as long as the first position A is not located on the side of the fourth position D away from the second position B, and the third position C is not located on the side of the second position B away from the fourth position D.

Optionally, in one embodiment of the present disclosure, as shown in FIG. 10, the first position A and the second position B are the same, and the third position is located on the side of the fourth position D away from the second position B, so as to reduce a length of the (i+1) third pixel opening 103 in the second direction Y, increase the distance between the i-th third pixel opening 103 and the (i+1) third pixel opening 103, improve the display quality of the display panel, such as color deviation or dispersion after the light modulation layer is superimposed.

It should be noted that in the above embodiment, as shown in FIG. 11, the size of the i-th third pixel opening 103 in the second direction Y can be the same as the size of the (i+1) third pixel opening 103 in the second direction Y, so that the area of the opening area of each third pixel opening 103 is the same, but the present disclosure does not limit this. In other embodiments of the present disclosure, the size of the i-th third pixel opening 103 in the second direction Y can also be different from the size of the (i+1) third pixel opening 103 in the second direction Y, as shown in FIG. 10, depending on a specific situation.

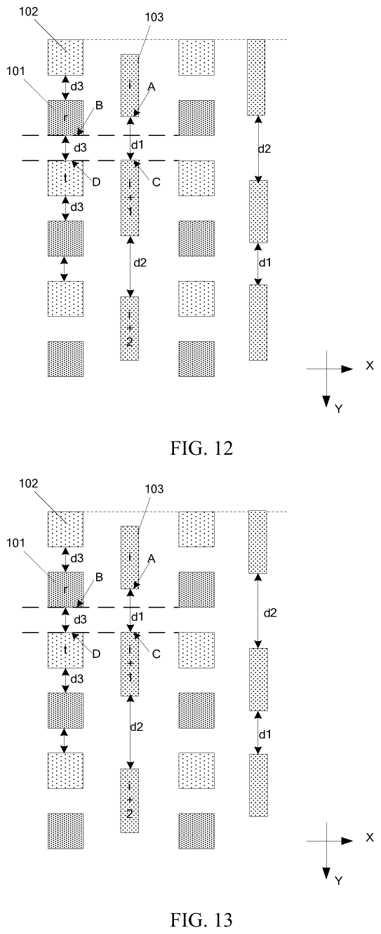

In another embodiment of the present disclosure, as shown in FIG. 12, the first position A is located on the side of the second position B away from the fourth position D, and the third position C is the same as the fourth position D, so as to reduce the length of the i-th third pixel opening 103 in the second direction Y, increase the distance between the i-th third pixel opening 103 and the (i+1)-th third pixel opening 103, improve the display quality of the display panel, such as color deviation or dispersion, by superimposing the light modulation layer in the display panel.

It should be noted that in the above embodiment, as shown in FIG. 13, the size of the i-th third pixel opening 103 in the second direction Y can be the same as the size of the (i+1)-th third pixel opening 103 in the second direction Y, so that the area of the opening area corresponding to each third pixel opening 103 is the same, but the present disclosure does not limit this. In other embodiments of the present disclosure, the size of the i-th third pixel opening 103 in the second direction Y can also be different from the size of the (i+1)-th third pixel opening 103 in the second direction Y, as shown in FIG. 12, depending on a specific situation.

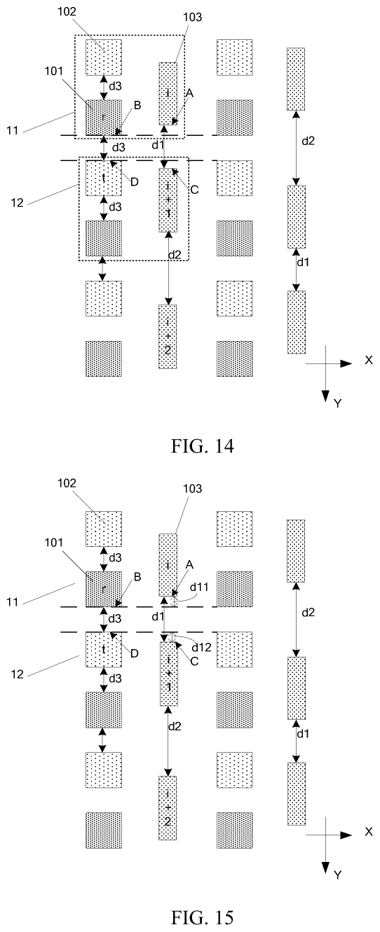

In another embodiment of the present disclosure, as shown in FIG. 14, the first position A and the second position B are different, and the third position C and the fourth position D are different, so as to reduce the length of the i-th third pixel opening 103 in the second direction Y and the length of the (i+1)-th third pixel opening 103 in the second direction Y, increase the distance between the i-th third pixel opening 103 and the (i+1)-th third pixel opening 103, improve the poor display phenomenon such as color deviation or dispersion after the light modulation layer is superimposed in the display panel, and improve the display quality of the display panel.

It should be noted that in the embodiment of the present disclosure, as shown in FIG. 14, in the second direction Y, the first position A is located on the side of the fourth position D toward the second position B, and the third position C is located on the side of the second position B toward the fourth position D, so that the display effects of the display areas corresponding to the first pixel unit area 11 and the second pixel unit area 12 can be independent of each other, reducing the mutual influence between the display contents corresponding to the first pixel unit area 11 and the second pixel unit area 12. However, the present disclosure does not impose any limitation on this, as long as the first position A is not located on the side of the fourth position D away from the second position B, and the third position C is not located on the side of the second position B away from the fourth position D.

Optionally, based on the above embodiments, in one embodiment of the present disclosure, as shown in FIG. 14, the first position A is located on the side of the second position B away from the fourth position D, and the third position C is located on the side of the fourth position D away from the second position B, so as to further reduce the mutual influence between the display contents corresponding to the first pixel unit area 11 and the second pixel unit area 12.

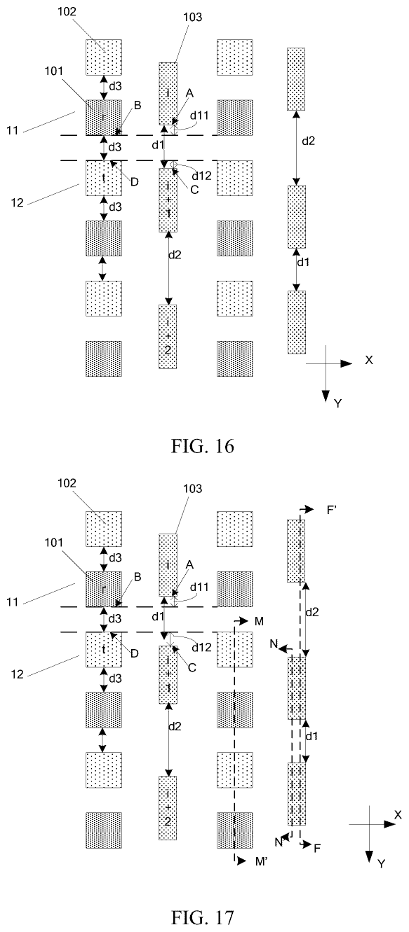

Based on the above implementation, in one embodiment of the present disclosure, as shown in FIG. 14 and FIG. 15, there is a first distance d11 between the first position A and the second position B, and there is a second distance d12 between the third position C and the fourth position D. Optionally, in one embodiment of the present disclosure, the first distance d11 is equal to the second distance d12, so as to balance the uniformity of the display effect when the first pixel unit area 11 and the second pixel unit area 12 display the same content, but the present disclosure does not limit this. In other embodiments of the present disclosure, the first distance d11 may also be greater than the second distance d12, as shown in FIG. 16, or less than the second distance d12, as shown in FIG. 17, depending on a specific situation.

It should be noted that, compared with the display panel adopting a setting mode that the first distance d11 is greater than the second distance d12, or less than the second distance d12, the display panel adopts the setting mode that the first distance d11 is equal to the second distance d12, which has a better effect on improving the display quality of the display panel; the display panel adopts the setting mode that the first distance d11 is greater than the second distance d12 and the display panel adopts the setting mode that the first distance d11 is less than the second distance d12, which has basically the same effect on improving the display quality of the display panel.

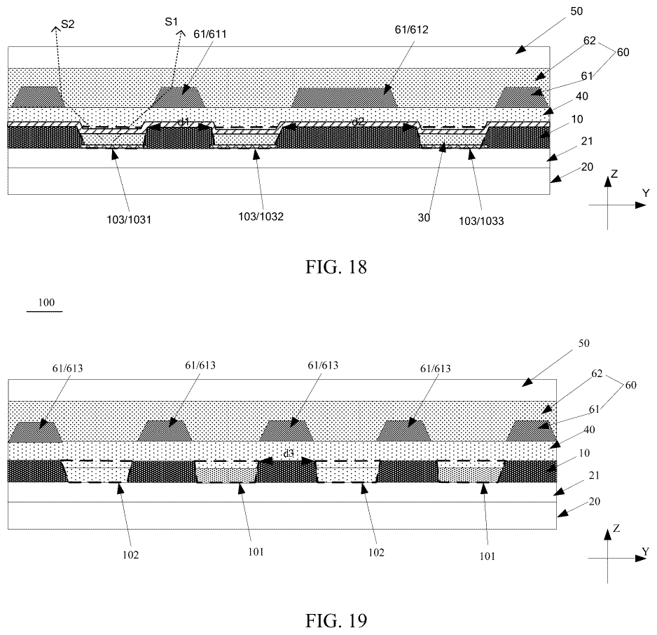

Based on any of above embodiments, in one embodiment of the present disclosure, as shown in FIG. 18, FIG. 18 is a cross-sectional view of FIG. 17 along FF′ direction, the display panel further includes: a light modulation structure 60 located on the side of the pixel definition layer 10 away from the array substrate 20, and the light modulation structure 60 includes a plurality of first light modulation parts 61. In this embodiment, there is a gap between adjacent pixel openings (such as d1, d2), and a first light modulation portion 61 corresponds to a gap between adjacent pixel openings, that is, there is a gap between adjacent light-emitting functional layers 30, and a first light modulation portion 61 corresponds to the gap between adjacent light-emitting functional layers 30, and in the third direction Z, the first light modulation portion 61 overlaps with a corresponding gap, and the third direction Z is perpendicular to a plane where the display panel is located. That is, in this embodiment, as shown in FIG. 18 and FIG. 19, FIG. 19 is a cross-sectional view of FIG. 17 along MM′. Due to the large number of labels, in order to facilitate the display of labels and their corresponding positions, at the pixel opening position, FIG. 19 and subsequent cross-sectional views no longer show the anode layer and the cathode layer. The first light modulating portion 61 is correspondingly arranged above the gap between any two adjacent first pixel openings 101 and the second pixel opening 102, and the first light modulating portion 61 is also correspondingly arranged above the gap between any two adjacent third pixel openings 103, so that the first light modulating portion 61 is correspondingly arranged above the gap between any two adjacent pixel openings, thereby improving the color deviation or dispersion and other display defects caused by the gap between the i-th third pixel opening 1031 and the (i+1)-th third pixel opening 1032 being too small, and the first light modulating portion 61 cannot be arranged above the gap, thereby improving the display quality of the display panel.

Specifically, in one embodiment of the present disclosure, as shown in FIGS. 18 and 19, the plurality of first light modulation parts 61 include a first sub-light modulation part 611, a second sub-light modulation part 612 and a third sub-light modulation part 613.

In the second direction Y, there is a first gap d1 between the i-th third pixel opening 1031 and the (i+1)-th third pixel opening 1032; in the third direction Z, the first sub-light modulation part 611 overlaps with the first gap d1.

In the second direction Y, there is a second gap d2 between the (i+1)-th third pixel opening 1032 and the (i+2)-th third pixel opening 1033; in the third direction Z, the second sub-light modulation part 612 overlaps with the second gap d2.

In the second direction Y, there is a third gap d3 between the adjacent first pixel opening 101 and the second pixel opening 102; in the third direction Z, the third sub-light modulation part 613 overlaps with the third gap d3.

Optionally, in one embodiment of the present disclosure, as shown in FIG. 18, d1<d2, in the second direction Y, a width of the second sub-light modulation portion 612 is greater than a width of the first sub-light modulation portion 611. In the present embodiment, optionally, d1 is greater than 6 μm to ensure an improvement effect on the display quality of the display panel without increasing a process difficulty of the first light modulation portion 61; the present disclosure does not limit this. In other embodiments of the present disclosure, d1>d2 may also be used. Accordingly, in the second direction Y, the width of the second sub-light modulation portion 612 is less than the width of the first sub-light modulation portion 611, depending on a specific situation.

It should be noted that in the above embodiment, if d3<d1; then in the second direction Y, the width of the first sub-light modulation portion 611 is greater than the width of the third sub-light modulation portion 613, and if d3 is equal to d1; then in the second direction Y, the width of the first sub-light modulation portion 611 is equal to a width of the third sub-light modulation portion 613.

On the basis of any of the above embodiments, in one embodiment of the present disclosure, as shown in FIGS. 18 and 19, the light modulation structure 60 also includes: a second light modulation part 62 located on the side of the first light modulation part 61 away from the array substrate 20, covering the display area of the display panel, the second light modulation part 62 has a different refractive index from the first light modulation part 61, so as to utilize an interface between the first light modulation part 61 and the second light modulation part 62 to form a functional interface, and the functional interface can be used to redirect the large-angle light emitted by the light-emitting functional layer 30. After the function interface acts, the light is deflected toward the normal viewing direction of the display panel, reducing a probability of total reflection of the light inside the display panel, thereby improving the light extraction efficiency of the light-emitting functional layer 30, and further improving the light-emitting efficiency of the display panel.

Optionally, in one embodiment of the present disclosure, as shown in FIG. 18, a refractive index of the first light modulating portion 61 is less than the refractive index of the second light modulating portion 62. In this embodiment, when the large-angle light emitted by the light-emitting functional layer 30 is emitted from the first light modulating portion 61 to the second light modulating portion 62, the light is emitted from the optically sparse medium to the optically dense medium, and an incident angle is greater than a refraction angle. Compared with an incident light, an angle between the refracted light emitted from the second light modulating portion 62 and the third direction Z becomes smaller, such as the light S1, that is, the light emitted from the second light modulating portion 62 is deflected toward the normal viewing direction of the display panel, thereby reducing the probability of total reflection of the light inside the display panel, improving the light extraction efficiency of the light-emitting functional layer 30, and improving the luminous efficiency of the display panel. When the large-angle light emitted by the light-emitting functional layer 30 is emitted from the second light modulating portion 62 to the first light modulating portion 61, the light is emitted from the optically dense medium to the optically sparse medium, and total reflection can occur when the incident angle is greater than the critical angle. Compared with the incident light, the angle between the total reflected light and the third direction Z is also smaller, such as light S2, which can also improve the light extraction efficiency of the light-emitting functional layer 30, thereby improving the light extraction efficiency of the display panel.

Optionally, in the above embodiment, in the third direction Z, the first light modulation part 61 covers the corresponding gap, so that the first light modulation part 61 and the second light modulation part 62 can modulate more large-angle light, improve the light extraction efficiency of the light-emitting functional layer 30, and thus improve the light extraction efficiency of the display panel.

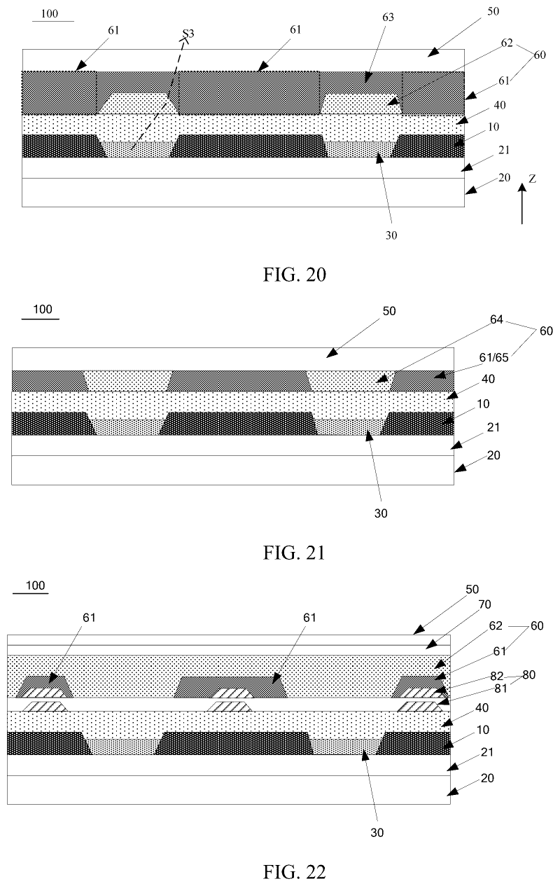

In another embodiment of the present disclosure, as shown in FIG. 20, a plurality of light modulation parts 61 are different components of the same light modulation layer 63, and the light modulation layer 63 covers the display area of the display panel. It should be noted that in this embodiment, the light modulation structure also includes: a second light modulation part 62 located between the light modulation layer 63 where the first light modulation part 61 is located and a plurality of light emitting functional layers 30, and the second light modulation part 62 includes a plurality of sub-light modulation parts, one sub-light modulation part corresponds to one light emitting functional layer 30, and is located above the corresponding light emitting functional layer 30. In this embodiment, the refractive index of the second light modulation part 62 is different from that of the first light modulation part 61, so as to form a functional interface by utilizing the interface between the first light modulation part 61 and the second light modulation part 62, and the functional interface can turn the large-angle light emitted by the light emitting functional layer 30, and after the function of the functional interface, the light is deflected toward the normal viewing direction of the display panel, reducing the probability of total reflection of the light inside the display panel, thereby improving the light extraction efficiency of the light emitting functional layer 30, and further improving the light emitting efficiency of the display panel.

Optionally, in one embodiment of the present disclosure, the refractive index of the first light modulating part 61 is less than the refractive index of the second light modulating part 62. In this embodiment, the large-angle light emitted by the light-emitting functional layer 30 is emitted from the second light modulating part 62 to the first light modulating part 61, which is emitted from the light-dense medium into the light-sparse medium, and the refraction angle is greater than the incident angle. Compared with the incident light, the angle between the refracted light and the third direction Z is also smaller, so that the large-angle light is deflected toward the normal viewing direction of the display panel, such as light S3, reducing the probability of total reflection of the light inside the display panel, which can improve the light extraction efficiency of the light-emitting functional layer 30, thereby improving the light extraction efficiency of the display panel.

Optionally, in the above embodiment, in the third direction Z, the second light modulating part 62 covers the corresponding light-emitting functional layer 30, so that the first light modulating part 61 and the second light modulating part 62 can modulate more large-angle light, improve the light extraction efficiency of the light-emitting functional layer 30, thereby improving the light extraction efficiency of the display panel.

In another embodiment of the present disclosure, as shown in FIG. 21, the first light modulating part 61 is a component of the light shielding layer 65, and the light shielding layer 65 has a plurality of openings, and openings correspond to the light emission area of the light emitting functional layer 30, so as to use the first light modulating part 61 to reduce an amount of light reflected in the non-opening area of the display panel, improve the display quality of the display panel, and at the same time use the openings in the light shielding layer 65 to transmit the light emitted by the light emitting functional layer 30, so that the setting of the light shielding layer 65 does not affect the display of the display content of the display panel. Optionally, in this embodiment, as shown in FIG. 18, the distance d1 between the i-th third pixel opening 1031 and the (i+1)-th third pixel opening 1032 is greater than 4 μm, so as to ensure the improvement effect on the display quality of the display panel, and do not increase the process difficulty of the first light modulating part 61. However, this application does not limit this, and the distance d1 depends on a specific situation.

Optionally, based on the above embodiment, in one embodiment of the present disclosure, as shown in FIG. 21, the display panel further includes: a color resist unit 64 located in the opening, so as to use the color resist unit 64 to reduce the amount of light reflected in the opening area of the display panel, thereby improving the display quality of the display panel.

It should be noted that, in the present embodiment, the color resist unit in the display panel includes the color resist unit of a first color, the color resist unit of a second color, and the color resist unit of a third color, wherein the color resist unit of the first color is located above the first pixel opening, so that the area where the first pixel opening is located can transmit the light of the first color, the color resist unit of the second color is located above the second pixel opening, so that the area where the second pixel opening is located can transmit the light of the second color, and the color resist unit of the third color is located above the third color, so that the area where the third pixel opening is located can transmit the light of the third color, thereby using the color resist unit to reduce the amount of light reflected by the display panel, so that the display panel can achieve full-color display. Optionally, the first color is red, the second color is green, and the third color is blue, but the present disclosure does not limit this, and the color depends on a specific situation.

Based on any of the above embodiments, in one embodiment of the present disclosure, as shown in FIG. 21, the display panel further includes: a flat layer 21 located between the array substrate 20 and the pixel definition layer 10, and the flat layer 21 is used to provide a flat manufacturing surface for the light-emitting functional layer 30 and the pixel definition layer 10.

Optionally, based on the above embodiments, in one embodiment of the present disclosure, as shown in FIG. 21, the display panel further includes a thin film encapsulation layer 40 covering multiple light-emitting functional layers 30, and a thin film encapsulation layer 40 is used to isolate water and oxygen to ensure the service life of the light-emitting functional layer 30. Optionally, the thin film encapsulation layer 40 includes at least one inorganic layer and at least one organic layer.

Based on any of above embodiments, in one embodiment of the present disclosure, as shown in FIG. 21, the display panel further includes: a protective cover plate 50 located on the side of the light modulation structure 60 away from the array substrate 20, which is used to protect the internal structure of the display panel.

Based on any of above embodiments, in one embodiment of the present disclosure, as shown in FIG. 22, the display panel further includes: a touch layer 80 located between the light modulation structure 60 and the thin film encapsulation layer 40, so that the display panel is integrated with the touch function. Optionally, the touch layer 80 includes a first touch layer 81 and a second touch layer 82, and an insulating layer is provided between the first touch layer 81 and the second touch layer 82 to realize touch detection using the first touch layer 81 and the second touch layer 82.

Based on any of above embodiments, in one embodiment of the present disclosure, as shown in FIG. 22, the display panel may further include: a polarizer 70, which is located between the light modulation structure 60 and the protective cover plate 50, so as to reduce the amount of light reflected from the display surface of the display panel and improve the display quality.

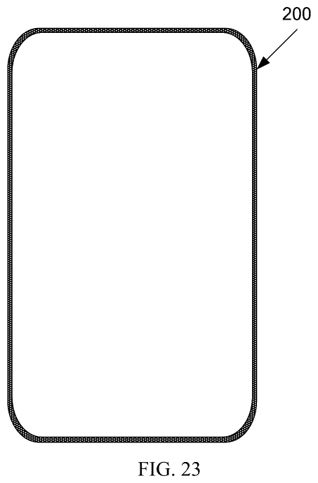

In addition, as shown in FIG. 23, the embodiment of the present disclosure further provides a display device 200, which includes a display panel provided by any of the above embodiments. Optionally, the display device 200 can be a mobile phone, a tablet computer, a wearable device, a vehicle-mounted device, an augmented reality (AR)/virtual reality (VR) device, a notebook computer, an ultra-mobile personal computer (UMPC), a netbook, a personal digital assistant (PDA), etc., and the embodiment of the present disclosure does not impose any restrictions on this.

As such, in the display panel and the display device provided in embodiments of the present disclosure, a first light-emitting functional layer is arranged in the first pixel opening, a second light-emitting functional layer is arranged in the second pixel opening, and a third light-emitting functional layer is arranged in the third pixel opening. In the second direction Y, the spacing between the i-th third pixel opening 103 and the (i+1)-th third pixel opening 103 is d1, and the spacing between the (i+1)-th third pixel opening 103 and the (i+2)-th third pixel opening 103 is d2, and d1≠d2, so that during the formation of the third light-emitting functional layer, the i-th third pixel opening 103 and the (i+1)-th third pixel opening 103 can share the opening of the mask, thereby improving the i-th third pixel opening 103 and The aperture ratio of the (i+1) third pixel opening 103, or the (i+1) third pixel opening 103 and the (i+2) third pixel opening 103 can share an opening of a mask, thereby improving the aperture ratio of the (i+1) third pixel opening 103 and the (i+2) third pixel opening 103, thereby improving the display brightness of the third light-emitting functional layer in the display panel, and improving the display quality of the display panel, that is, using two third light-emitting functional layers adjacent in the second direction Y and with a small spacing to share the opening of the mask, to improve the aperture ratio of the third light-emitting functional layer in the display panel, and then under the same driving signal, improve the display brightness of the third light-emitting functional layer in the display panel, and finally improve the display quality of the display panel.

Moreover, in the display panel and display device provided by the embodiment of the present disclosure, in the second direction Y, the spacing between the adjacent first pixel openings 101 and the second pixel openings 102 is d3, d1≥d3, and d2≥d3, so that the distance between the two adjacent third pixel openings 103 with a smaller distance can be increased, so that the light modulation layer can be set above the gap between any two adjacent third pixel openings 103 in the second direction Y, thereby alleviating the phenomenon that the display quality deteriorates due to the small size of the gap between some adjacent third pixel openings 103 and the inability to set the light modulation layer, thereby improving the display quality of the display panel.

In the display panel and display device provided in the embodiment of the present disclosure, a first light-emitting functional layer is arranged in the first pixel opening, a second light-emitting functional layer is arranged in the second pixel opening, and a third light-emitting functional layer is arranged in the third pixel opening. In the second direction, the spacing between the i-th third pixel opening and the (i+1)-th third pixel opening is d1, and the spacing between the (i+1)-th third pixel opening and the (i+2)-th third pixel opening is d2, d1≠d2, so that during the formation of the third light-emitting functional layer, the i-th third light-emitting functional layer and the (i+1)-th third light-emitting functional layer can share an opening of the mask, increasing the spacing between the i-th third light-emitting functional layer and the i+1 third light-emitting functional layer, or, the (i+1)-th third light-emitting functional layer and the (i+2)-th third light-emitting functional layer can share an opening of the mask, thereby increasing the opening ratio of the (i+1)-th third light-emitting functional layer and the (i+2)-th third light-emitting functional layer, thereby increasing the display brightness of the third light-emitting functional layer in the display panel, and improving the display quality of the display panel, that is, using two third light-emitting functional layers adjacent in the second direction and with a small spacing to share an opening of the mask, to increase the opening ratio of the third light-emitting functional layer in the display panel, and then under the same driving signal, increase the display brightness of the third light-emitting functional layer in the display panel, and finally improve the display quality of the display panel.

Moreover, in the display panel and the display device provided by the embodiments of the present disclosure, in the second direction, the spacing between adjacent first pixel openings and second pixel openings is d3, d1≥d3 and d2≥d3, so that the distance between two adjacent third pixel openings with a smaller distance is increased, so that a light modulation layer can be set above the gap between any two adjacent third pixel openings in the second direction, thereby alleviating the phenomenon that the display quality deteriorates due to the small size of the gap above some adjacent third pixel openings and the inability to set the light modulation layer, thereby improving the display quality of the display panel

In this specification, each embodiment is described in a progressive, or parallel, or progressive and parallel combination manner, and each embodiment focuses on the differences from other embodiments, and the same and similar parts between embodiments can refer to each other. For the device disclosed in the embodiment, since the device corresponds to the method disclosed in the embodiment, the description is relatively simple, and the relevant parts can refer to the method part description.

It should be noted that in the description of the present disclosure, it should be understood that the description of the drawings and embodiments is illustrative rather than restrictive. It should also be noted that, in this article, relational terms such as first and second, etc. are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that an article or device including a series of elements includes not only those elements, but also other elements not explicitly listed, or also includes elements inherent to such article or device. In the absence of further restrictions, the elements defined by the sentence “including one . . . ” do not exclude the existence of other identical elements in the article or device including the above elements.

The above description of the disclosed embodiments enables professionals in this field to implement or use the present disclosure. Various modifications to these embodiments will be obvious to professionals in this field, and the general principles defined herein can be implemented in other embodiments without departing from the spirit or scope of the present disclosure. Therefore, the present disclosure will not be limited to embodiments shown herein, but will conform to the widest scope consistent with the principles and novel features disclosed herein.

What is claimed is:

1. A display panel, comprising:
an array substrate;
a pixel definition layer located on a side of the array substrate, the pixel definition layer comprising a plurality of pixel openings; and
a light-emitting functional layer located within a pixel opening of the plurality of pixel openings;
the plurality of pixel openings comprising:
a first column of pixel openings and a second column of pixel openings arranged along a first direction, the first column of pixel openings comprising a first pixel opening and a second pixel opening periodically arranged along a second direction, the second column of pixel openings comprising an i-th third pixel opening, an (i+1)-th third pixel opening and an (i+2)-th third pixel opening arranged along the second direction, i being an integer not less than 1; wherein
in the second direction, a spacing between the i-th third pixel opening and the (i+1)-th third pixel opening is d1, a spacing between the (i+1)-th third pixel opening and the (i+2)-th third pixel opening is d2, d1≠d2, i is a positive integer not greater than N-2, and N is an integer greater than 4;
in the second direction, a spacing between adjacent first and second pixel openings is d3;
wherein the first pixel opening is provided with a first light-emitting functional layer, the second pixel opening is provided with a second light-emitting functional layer, and the third pixel opening is provided with a third light-emitting functional layer; d1≥d3, and d2≥d3.

2. The display panel according to claim 1, wherein in the second direction, a spacing between a (2k+1)-th third pixel opening and a (2k+2)-th third pixel opening is d1, and k is an integer not less than 0; and
in the second direction, a spacing between a (2j+2)-th third pixel opening and a (2j+3)-th third pixel opening is d2, and j is an integer not less than 0.

3. The display panel according to claim 1, wherein d1<d2; the i-th third pixel opening and an r-th first pixel opening are located in a same row, the (i+1)-th third pixel opening and a t-th second pixel opening are located in a same row, the r-th first pixel opening and the t-th second pixel opening are located in adjacent rows, r is an integer not less than 1, and t is an integer not less than 1.

4. The display panel according to claim 3, wherein in the second direction, the i-th third pixel opening has a first position toward a boundary of the (i+1)-th third pixel opening, and the r-th first pixel opening has a second position toward the boundary of the t-th second pixel opening; and
in the second direction, the first position and the second position are same.

5. The display panel according to claim 3, wherein in the second direction, the (i+1)-th third pixel opening has a third position toward a boundary of the i-th third pixel opening, and the t-th second pixel opening has a fourth position toward a boundary of the r-th first pixel opening; and
in the second direction, the third position and the fourth position are same.

6. The display panel according to claim 3, wherein in the second direction, the i-th third pixel opening has a first position toward the boundary of the (i+1)-th third pixel opening, the r-th first pixel opening has a second position toward the boundary of the t-th second pixel opening, the (i+1)-th third pixel opening has a third position toward the boundary of the i-th third pixel opening, and the t-th second pixel opening has a fourth position toward the boundary of the r-th first pixel opening; and
in the second direction, the first position is same as the second position, and the third position is same as the fourth position.

7. The display panel according to claim 3, wherein in the second direction, the i-th third pixel opening has a first position toward the boundary of the (i+1)-th third pixel opening, the r-th first pixel opening has a second position toward the boundary of the t-th second pixel opening, the (i+1)-th third pixel opening has a third position toward the boundary of the i-th third pixel opening, and the t-th second pixel opening has a fourth position toward the boundary of the r-th first pixel opening; and
in the second direction, the first position is different from the second position, and the third position is different from the fourth position.

8. The display panel according to claim 7, wherein d1>d3.

9. The display panel according to claim 8, wherein in the second direction, the first position is located on a side of the second position away from the fourth position, and the third position is located on a side of the fourth position away from the second position.

10. The display panel according to claim 9, wherein in the second direction, a first distance is between the first position and the second position, and a second distance is between the third position and the fourth position; and
the first distance equals to the second distance, or the first distance is greater than the second distance, or the first distance is less than the second distance.

11. The display panel according to claim 7, wherein in the second direction, the first position is located on a side of the fourth position facing the second position, and the third position is located on a side of the second position facing the fourth position.

12. The display panel according to claim 1, further comprising:
a light modulation structure located on a side of the pixel definition layer away from the array substrate, the light modulation structure comprising a plurality of first light modulation parts, wherein
a gap is between adjacent pixel openings, one first light modulation part corresponds to the gap between adjacent pixel openings, and in a third direction, the first light modulation part overlaps with a corresponding gap, and the third direction is perpendicular to a plane where the display panel is located.

13. The display panel according to claim 12, wherein in the third direction, the first light modulation part covers the corresponding gap.

14. The display panel according to claim 12, wherein d1<d2, and the plurality of the first light modulation parts comprises:
a first sub-light modulation part;
a second sub-light modulation part; and
a third sub-light modulation part,
wherein
in the second direction, a first gap is between the i-th third pixel opening and the (i+1)-th third pixel opening, and in the third direction, the first sub-light modulation part overlaps with the first gap;
in the second direction, a second gap is between the (i+1)-th third pixel opening and the (i+2)-th third pixel opening, and in the third direction, the second sub-light modulation part overlaps with the second gap;
in the second direction, a third gap is between the adjacent first and second pixel openings, and in the third direction, the third sub-light modulation part overlaps with the third gap; and
in the second direction, a width of the second sub-light modulation part is greater than a width of the first sub-light modulation part.

15. The display panel according to claim 14, wherein d3<d1; in the second direction, the width of the first sub-light modulation part is greater than a width of the third sub-light modulation part.

16. The display panel according to claim 12, wherein the light modulation structure further comprises: a second light modulation part located on a side of the first light modulation part away from the array substrate and covering a display area of the display panel, and a refractive index of the second light modulation part is different from that of the first light modulation part.

17. The display panel according to claim 12, wherein he first light modulation part is a component of a light shielding layer, the light shielding layer includes a plurality of openings, and the plurality of openings correspond to light emitting areas of light emitting units; and the display panel further comprises: a color resistance unit located in an opening of the plurality of openings.

18. The display panel according to claim 12, further comprising:
a thin film encapsulation layer located on a side of the light emitting unit away from the array substrate; and
a touch layer located between the light modulation structure and the thin film encapsulation layer.

19. The display panel according to claim 1, wherein the first light-emitting functional layer is a red light-emitting functional layer, the second light-emitting functional layer is a green light-emitting functional layer, and the third light-emitting functional layer is a blue light-emitting functional layer.

20. A display device comprising a display panel, the display panel comprising:
an array substrate;
a pixel definition layer located on a side of the array substrate, the pixel definition layer comprising a plurality of pixel openings; and
a light-emitting functional layer located within a pixel opening of the plurality of pixel openings;
the plurality of pixel openings comprising:
a first column of pixel openings and a second column of pixel openings arranged along a first direction, the first column of pixel openings comprising a first pixel opening and a second pixel opening periodically arranged along a second direction, the second column of pixel openings comprising an i-th third pixel opening, an (i+1)-th third pixel opening and an (i+2)-th third pixel opening arranged along the second direction, i being an integer not less than 1; wherein
in the second direction, a spacing between the i-th third pixel opening and the (i+1)-th third pixel opening is d1, a spacing between the (i+1)-th third pixel opening and the (i+2)-th third pixel opening is d2, d1≠d2, i is a positive integer not greater than N-2, and N is an integer greater than 4;
in the second direction, a spacing between adjacent first and second pixel openings is d3;
wherein the first pixel opening is provided with a first light-emitting functional layer, the second pixel opening is provided with a second light-emitting functional layer, and the third pixel opening is provided with a third light-emitting functional layer; d1≥d3, and d2≥d3.
